(19) United States
(12) Patent Application Publication
(10) Pub. No.: US 2006/0270219 A1
(43) Pub. Date: Nov. 30, 2006

(54) Reducing stress in coatings produced by physical vapour deposition technical field

(76) Inventors: Xu Shi, Singapore (SG); Li Kang Cheah, Singapore (SG)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/407,062

(22) Filed: Apr. 20, 2006

Related U.S. Application Data
(63) Continuation-in-part of application No. 11/036,986, filed on Jan. 19, 2005.

(30) Foreign Application Priority Data
Jan. 21, 2004 (GB) 0401295.1

(51) Int. Cl. H04B 15/00; H01L 21/44

(52) U.S. Cl. 438/678; 381/94.3

(57) ABSTRACT

Coatings are deposited using arc-based deposition methods using a large negative bias on the substrate, of −1,500 V or more negative, which is varied during deposition, resulting in reduced stress in the coating.

### TECHNICAL FIELD

The invention relates to reducing stress in coatings deposited with arc deposition devices, especially those which enable a substrate to be biased with a large negative voltage.

### BACKGROUND

A number of plasma-based deposition methods have in recent years replaced sputtering systems as the desirable means of depositing thin coatings on a wide range of substrates.

It is known to use voltage-biasing of a substrate during deposition of a coating via physical vapour deposition (PVD) processes. This voltage biasing tends to be at a constant level throughout the deposition phase, at potentials of about −1,000 V or about −600 V. For example, Ionbond® produces a range of PVD devices, one of which has the designation ‘PVD-3501, in which a substrate is biased at a constant voltage of −1,000 V, This biasing prevents any build-up of positive electrostatic potential and enables films of acceptable depth to be deposited.

A problem with coatings produced by this and other known methods is that whilst they can have very high levels of hardness, there is also a high level of stress in the coating. This restricts the coating depth and the possible applications for which the coated products can be used.

There is hence a need for coatings of a lower stress, enabling the coatings to stick to the substrate with greater ease, be more flexible (i.e. less brittle), have a greater thickness and/or have an improved consistency.

There is a need to provide a method and apparatus for deposition of coatings having reduced stress than hitherto possible. There is a further need to provide a coating having an improved stress-level is produced. There is a further need to enable a thicker coating to be deposited onto the substrate, with a higher consistency than has been previously achieved.

### SUMMARY

An first aspect of the invention provides a method for coating a substrate, comprising the steps of:

creating a plasma of a coating material;

depositing plasma on the substrate; and

biasing the substrate using a variable bias.

A second aspect of the invention provides a system for coating a substrate comprising:

a vacuum chamber for locating the substrate;

an anode and cathode assembly capable of generating a plasma within the vacuum chamber from a target and thereby deposit the plasma on the substrate to form a coating;

a power supply capable of applying bias to the substrate, wherein in use, said power supply applies a variable bias to the substrate as said plasma is deposited thereon.

A third aspect of the invention provides an apparatus for coating a substrate comprising:

a vacuum chamber for locating the substrate;

an anode and cathode assembly capable of generating a plasma within the vacuum chamber from a target;

a power supply capable of applying bias to the substrate,

wherein in use, said power supply applies a variable bias to said substrate as said plasma is deposited on said substrate to form a coating thereon.

An fourth aspect of the invention provides the use of a variable bias voltage for reducing stress in a coating deposited using an arc deposition apparatus.

### DISCLOSURE OF EMBODIMENTS

Exemplary, non-limiting embodiments of a method for coating a substrate, a coating system and apparatus will now be disclosed.

The variable bias may alternate between a high negative bias pulse and a low negative bias pulse. The high negative bias pulse may be selected from the group consisting of the range −1800 V to −4,500 V and −2000 V to −2500 V. The low negative bias pulse may be selected from the group consisting of the range −50 V to −500 V and −100 V to −200 V. Pulsing of the bias on the substrate may undertaken at a frequency of up to 10 kHz or from 1 kHz to 3 kHz. The duration of the pulses may be undertaken for a time period selected from the group consisting of 1 μs to 25 or 1 μs to 25 μs or 5 μs to 10 μs.

The plasma may be created from a target located in a vacuum chamber of an arc deposition apparatus comprising an anode and a cathode. The target may be a metal target or a graphite target. The metal target may be a metal selected from the group consisting of titanium, chromium, aluminum, gallium and mixtures or alloys thereof.

The arc deposition apparatus may comprise a filter to filter a cathodic vacuum arc source.

A gas may be introduced into the vacuum chamber to form a coating on the substrate which is a compound of the gas and the target.

Also disclosed herein in the use of a large negative bias applied to a substrate. Also disclosed herein is a method for coating a substrate, comprising:

creating a plasma of a coating material;

depositing plasma on the substrate; and

biasing the substrate at −1,500 V or more negative.

Advantageously, the use of this bias results in reduced stress of the applied film. In examples below, we have biased a titanium test-plate at −4,500 V and observed considerably lower stress levels in the applied film than those achieved when using a known fixed bias. Advantageously, we have also surprisingly found that if the magnitude of bias is varied when plasma is deposited on the substrate, a coating forms on the which has reduced stress and more hardness than if no bias is supplied to the substrate or if only a constant bias is applied to the substrate.

Preferably, deposition of a coating is carried out whilst both varying the bias on the substrate and applying a bias of −1,500 V or more negative.

In use, the bias applied to the substrate may suitably be up 5 to −10,000 V, preferably up to −5,000 V. Whilst a higher magnitude peak bias may be applied, we have found stress reduction to be achieved within these limits. The bias is further suitably −2,000 V or more negative. It is particularly preferred that the bias is in the range of from −2,000 V to −4,000 V for filtered cathodic vacuum arc (FCVA) sources and from −2,000 V to −3,000 V for other arc sources.

The disclosed coating methods may employ a variable or pulsed bias, varying from large negative values to zero or near zero. After peaking at, say, about −1,500 V the bias can return to much smaller values, such as at −300 V or less negative, preferably −200 V or less negative. This can to a certain extent depend upon the power supply used, and in examples below the pulse generally returns from its peak to a value from about −100 V to zero, going transiently positive on occasion. The variation in bias in the examples follows an approximately square wave pattern, though other variations are also suitable, including regular and irregular wave forms.

During deposition, the pulse duration and frequency typically follows a pre-set pattern. The pulse duration is generally short, and can be from 1-50 μs. For direct arc sources, the pulse duration is preferably from 1-20 μs, more preferably from 5-10 μs. For FCVA sources, the pulse duration is preferably from 1040 μs, more preferably from 15-25 μs. The frequency is generally rapid, of a few hundred or thousand pulses per second. A preferred method comprises pulsing the bias on the substrate at a frequency of up to 10 kHz, preferably from 1-3 kHz, more preferably from 1.5-2.5 kHz.

In embodiments of the present invention, the power supply has come from Nanofilm Technologies International (NTI), and is termed a “high voltage pulse generator” (HVPG). However, the skilled person will be aware that any power supply can be utilised that is capable of biasing a substrate as herein described.

We have deposited coatings of titanium nitride and tetrahedral amorphous carbon (ta-C) onto test substrates using various biasing voltages, pulse durations and frequency of pulses. For example, in one set-up, the HVPG was set to pulses of −4,500 V with a duration of 20 μs and a frequency of 10 kHz. We then tested the stress of the titanium nitride coatings produced by our pulsed-biasing method, and found them to be in the range of 1-2 GPa, commonly about 1 Gpa. This compares favorably to the stress of titanium nitride coatings produced without pulsed biasing, which we found to have a stress of at least 3 GPa. The disclosed method thus enables coatings to be deposited with low stress levels. This allows thicker coatings to be deposited, as prior art coatings are so brittle that they will not adhere to substrates once their depth exceeds certain values. This increases the application of this coating technology, as reduced stress films can now be applied to more flexible substrates (prior art films would peel away upon flexing).

The method is especially suited for producing coatings using arc-based deposition devices and methods, and hence, in a particular method of the invention, pulsed, large negative biasing of a substrate is carried out in a method for coating a substrate in an arc deposition apparatus, the apparatus comprising a vacuum chamber, a target, and an anode and a cathode for creating the plasma from the target.

In direct arc deposition, the target material is preferably a metal, and good results have been obtained using a target selected from titanium, chromium, aluminium, gallium or mixtures or alloys of any of the aforementioned. Biasing can also be applied when making composite or compound coatings, and a further method of the invention comprises introducing a gas into the vacuum chamber to form a coating on the substrate which is a compound of the gas and the target. Suitable gases include nitrogen and oxygen.

In FCVA deposition, the target material is preferably graphite, used for production especially of ta-C coatings, and metals can also be employed.

In a disclosed example of use of the method and apparatus, a titanium target is placed in electrical contact with the cathode of an arc deposition apparatus. A substrate is located at the substrate station and the chamber is evacuated to about 1 μTorr. Nitrogen gas is introduced into the chamber to an operating pressure of about 1-20 mTorr, and preferably 3 mTorr. An arc is then struck, and a deposit of titanium nitride is coated onto the substrate. The substrate is biased during deposition at from −2,000 V to −3,000 V, at a frequency from 1-3 kHz and using a pulse duration of from 5-10 μs. Deposition is continued until a coating of about 2-3 μm is achieved. After deposition, the stress of the coating is generally from 1-2 GPa, and the hardness generally about 2,500 kg/mm2.

In a further example of use of the method and apparatus, a graphite target is placed in electrical contact with the cathode of an FCVA deposition apparatus. A substrate is located at the substrate station and the chamber is evacuated to about 1 μTorr. No gas is introduced. An arc is then struck and a deposit of ta-C is coated onto the substrate. The substrate is biased during deposition at from −2,000 V to −4,000 V, at a frequency from 1.5-2.5 kHz and using a pulse duration of from 15-25 μs. Deposition is continued until a coating thickness of about up to 10 μm is achieved. After deposition, the stress of the coating is generally less than 1 GPa, with a hardness of generally about 25-40 GPa and wear resistance of generally about 1×10-8-3×10-8 mm3/Nm.

In a further embodiment of the invention, an FCVA coating process is carried out in at least two phases. The first phase employs a substrate bias of −3,000 V to −4,000 V at a frequency of 1.5-2.5 kHz and using a pulse duration of 15-25 μs. The second phase employs a substrate bias of −2,000 V to −3,500 V at a frequency of 1.5-2.5 kHz and using a pulse duration of 15-25 μs.

The coatings provided by the present invention can be used in a variety of applications, e.g. anvils can be coated, or tool punches can be coated to increase the lifespan of the punch, or semiconductors and media devices can be coated to afford greater protection. The advantages of the biasing of the invention include the production of a coating of lower stress, which enables flexibility and/or a thicker coating to be deposited.

Generally, the invention provides use of a bias voltage of −1,500 V or more negative for reducing stress in a coating deposited using an arc deposition apparatus and/or use of a variable bias voltage for reducing stress in a coating deposited using an arc deposition apparatus.

### BRIEF DESCRIPTION OF DRAWINGS

The accompanying drawings and tables illustrate disclosed embodiments and serves to explain the principles of the disclosed embodiment. It is to be understood, however, that the drawings are designed for purposes of illustration only, and not as a definition of the limits of the invention.

Table 1 shows various combinations of bias parameters that have been achieved using the high voltage pulse generator;

FIG. 1 shows an output pulse waveform used to bias a substrate in a method of the invention; and

FIG. 2 shows an output pulse waveform used to bias a substrate in a method of the invention.

FIG. 3 shows an output pulse waveform having a variable amplitude to bias a substrate in a disclosed example.

FIG. 4 shows a schematic view of a multi-layer coating made in a method a disclosed embodiment.

### DETAILED DESCRIPTION

We modified an existing PVD device so as to apply a bias to the substrate in, using a power supply obtained from Nanofilm Technologies International (NTI), termed a “high voltage pulse generator” (HVPG). The power unit has a control panel on which the parameters can be manually set. Also employed is a switching device insulated gate bipolar transistor (IGBT) which is protected against current overloads and short circuits. The generator assembly is also equipped with an output fuse.

The output range of the pulse generator is up to −10,000 V, preferably −5,000 V, and more preferably −2,000 V to −4,000 V, with the pulses lasting from between 1-50 μs; for direct arc sources preferably from between 1-20 μs, more preferably from between 5-10 μs, and for FCVA sources preferably from between 10-40 μs, more preferably 15-25 μs; and at a frequency of up to 10 kHz, preferably from 1-3 kHz, more preferably from 1.5-2.5 kHz.

The HVPG was associated with the PVD device, and connected to the substrate, most commonly via the substrate holder. During operation of the PVD device, the HVPG was set to deliver pulses of large negative voltage to the substrate. The HVPG was started and stopped either manually or via remote.

All of the coatings in the Examples below were undertaken using an FCVA apparatus developed by NTI and described in International patent application WO 96/26531, which is incorporated herein in its entirety for reference.

### EXAMPLE 1

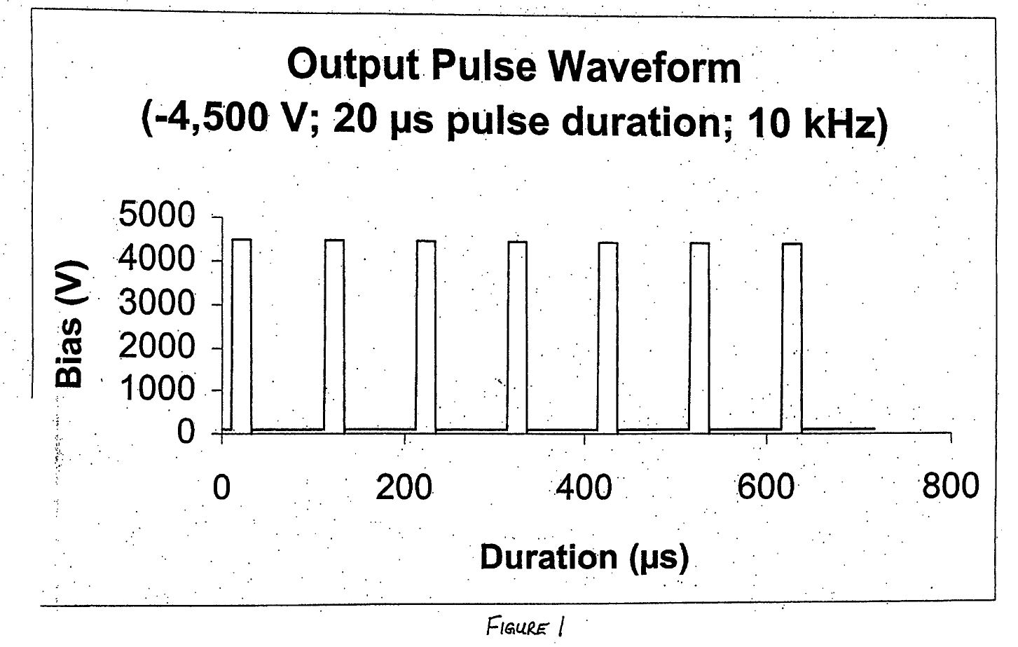

We deposited a coating of titanium nitride onto a test substrate (in this case, titanium plates approximately 5 cm×10 cm, 0.5 cm in depth) using a bias illustrated schematically in FIG. 1—i.e. the HVPG was set to pulses of −4,500 V with a duration of 20 μs and a frequency of 10 kHz.

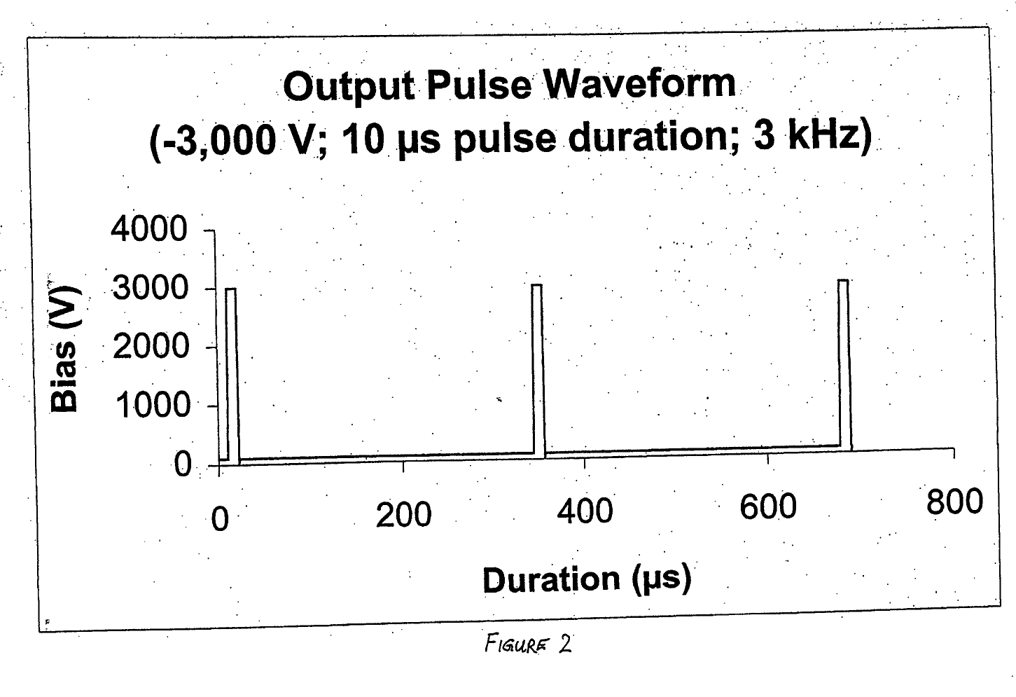

Similarly, we used a bias illustrated schematically in FIG. 2—i.e. the HVPG was set to pulses of −3,000 V with a duration of 10 μs and a frequency of 3 kHz.

We then tested the stress of the titanium nitride coatings, produced by our pulsed-biasing method, on the various test plates and found them to have values that were in the range of 1-2 GPa. The stress of a number of the tested coatings were found to have a value close to 1 GPa. This compares favorably to the stress of titanium nitride coatings produced without pulsed biasing, which we found to have a stress of at least 3 GPa.

We also tested the stress of the ta-C coatings, produced by our pulsed-biasing method, on the various test plates and found them to have values that were less than 1 GPa. The hardness was about 25-40 GPa and wear resistance was about 1×10-8-3×10-8 mm3/Nm.

Thus, the advantages of biasing of the invention include the production of a coating of lower stress, which enables flexibility and/or a thicker coating to be deposited.

TABLE 1

| Bias (V) | Duration (μs) | Frequency (kHz) |
|---|---|---|
| −4,500 | 20 | 10 |
| −4,500 | 2 | 10 |
| −4,500 | 2 | 1 |
| −3,000 | 10 | 3 |
| −3,000 | 5 | 1 |
| −2,000 | 8 | 2 |
| −2,000 | 10 | 2 |
| −4,000 | 25 | 2.5 |

### EXAMPLE 2

In this example, we made a coating of titanium nitride onto a test substrate having the same specifications as Example 1 above, except the HVPG was set to pulses of −50 V with a duration of 20 μs and a frequency of 10 kHz.

We then tested the stress number of the titanium nitride coatings, produced by our pulsed-biasing method, on the various test plates and found them to have values that were in close to 500 MPa to 1 GPa. While the coating produced had a relatively low stress, it did have a high hardness of about 40-50 GPa and wear resistance was about 0.8-12×10⁻⁸ mm³/Nm.

### EXAMPLE 3

While titanium nitride coating of example 2 in which the pulse-bias was −50V produced a coating having low stress, it had a relatively high hardness. The titanium nitride coating of example 1 in which the pulse-bias was −0500V produced a coating having high stress but a relatively low hardness (softness).

Accordingly, we found that using a low negative pulse bias produced coatings having relatively low stress with very high hardness. These coatings were prone to cracking, particularly when coatings having a thickness of 3 μm or more were made. Conversely, we found that using a high negative pulse bias produced coatings having high stress but which were too soft. These coatings were prone to excessive wearing as they had relatively low strength.

### EXAMPLE 4

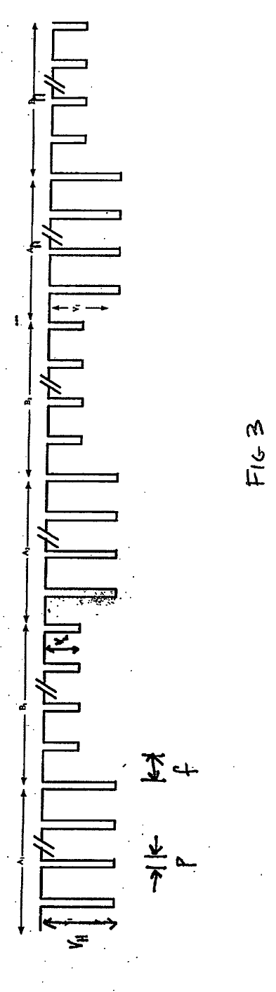

We investigated the possibilities of producing a coating that produced relatively low stress while not being either too hard or too soft. A coating of titanium nitride was made using a test substrate having the same specifications as Example 1 above. However, in this example, the bias was varied during the coating time as shown by FIG. 3. The HVPG was set to alternate between “N” times between a high negative bias (A₁, A₂ . . . A_{N}) having pulses V_{H} of −2,200 V and a low negative bias (B₁, B₂ . . . B_{N}) having pulses V_{L} of −100 V, both with a duration “p” of 20 μs and a frequency “f” of 10 kHz.

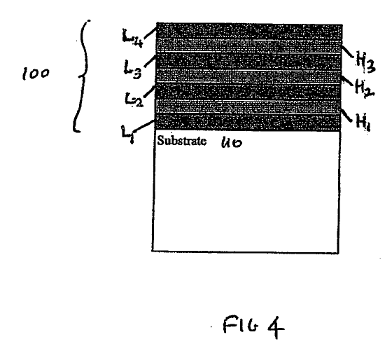

We found that by varying the amplitude of the negative bias during coating, the produced titanium nitride coatings had a lattice structure as shown by FIG. 4.

We then tested the stress number of the titanium nitride coatings, produced by our varying pulsed-biasing method, on the various test plates and found them to have values that were close to 400-800 MPa. The hardness was about 35-45 GPa. This compares favorably to the stress of titanium nitride coatings produced without pulsed biasing, which we found to have a stress of at least 3 GPa and showed an improvement over the coating produced in experiment 1 which were in the range of 1-2 GPa.

Thus, the advantages of biasing of the invention include the production of a coating of lower stress, which enables flexibility and/or a thicker coating to be deposited.

We have advantageously found that pulse bias can be varied between an alternating high pulse bias range and a relatively low pulse bias range. The high pulse bias range is in the range of −1800 V to −4,500 V, more preferably −2000 V to −2500 V. The low pulse bias range is in the range of −50 V to −500 V, more preferably −100 V to −200 V.

Referring again to FIG. 4, there is disclosed a schematic diagram of a multi-layered coating 100 formed on the substrate 110 when the bias is varied during coating. The coating 100 has alternating layers (L₁, L₂, L₃, L₄), produced when the bias voltage pulse is in the low pulse bias range, interleaved with layers (H₁, H₂, H₃), produced when the bias voltage pulse is in the low pulse bias range. Accordingly, by varying the bias, it has advantageously been found that a multi-layers coating 100 is formed in which layers (L₁, L₂, L₃, L₄) are relatively harder but have less relative stress than their neighboring alternating layers (H₁, H₂, H₃).

In one embodiment, the thickness of the coating layer produced by the high pulse bias range is about 2 to 10 nm, more preferably 2 to 5 nm. The thickness of the coating layer produced by the tow pulse bias range is about 2 to 5 nm, more preferably 1 to 2 nm.

Sample coatings from examples 2, 3 and 4 were subjected to Raman spectroscopic analysis wherein the peak intensities of each sample coating were obtained. It was found that the peak intensity (I_{D}/I_{G}) of the sample coatings which were subjected to the low negative bias only (coatings of example 2) which were relatively hard had a Raman intensity value of less than 0.3. On the other hand, the sample coatings which were subjected to the high negative bias only (coatings of example 3) which were relatively soft, had a Raman intensity values in the range 0.5 to 0.7. The sample coatings which were subjected to the alternating high and low negative pulse bias (coatings of example 4) were found to have Raman intensity values in the range 0.4 to 0.5. As will be known by persons skilled in the art, the Raman intensity values are indicative of the vibrational energies of molecules within the coatings. Hence, it has been observed that the coatings of example 4 have less stress relative to the coatings of example 3 (relatively soft coatings) but more stress relative to the coatings of example 2 (relatively hard coatings).

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method for coating a substrate, comprising the steps of:
(a) creating a plasma of a coating material;
(b) depositing plasma on the substrate; and
(c) biasing the substrate using a variable bias.

2. A method as claimed in claim 1, wherein said biasing step (c) comprises:
(c1), using a variable bias alternating between a high negative bias pulse and a low negative bias pulse.

3. A method as claimed in claim 2, wherein said using step (c1) comprises:
(c2) selecting said high negative bias pulse from the group consisting of the range −1800 V to −4,500 V and −2000 V to −2500 V.

4. A method as claimed in claim 2, wherein said using step (c1) comprises:
(c2) selecting said low negative bias pulse from the group consisting of the range −50 V to −500 V and −100 V to −200 V.

5. A method as claimed in claim 1, comprising the step of:
(d) pulsing the bias on the substrate at a frequency of up to 10 kHz

6. A method as claimed in claim 5, wherein said pulsing step (d) comprises the step of:
(d1) selecting the frequency from the range of 1 kHz to 3 kHz.

7. A method as claimed in claim 1, wherein said pulsing step (d) comprises the step of:
(d2) selecting the pulse duration from the group consisting of 1 μs to 50 μs, 1 μs to 25 μs, and 5 μs to 10 μs.

8. A method as claimed in claim 1, wherein said creating step (a) comprises:
(a1) creating plasma from a target located in a vacuum chamber of an arc deposition apparatus comprising an anode and a cathode.

9. A method as claimed in claim 8, comprising the step of:
(a2) filtering a cathodic vacuum arc source to create said plasma.

10. A method as claimed in claim 8, wherein said creating step (a) comprises:
(a3) using a metal as the target.

11. A method as claimed in claim 8, wherein said creating step (a) comprises:
(a4) using graphite as the target

12. A method as claimed in claim 10, wherein step (a3) comprises:
(a4) selecting the metal from the group consisting of titanium, chromium, aluminium, gallium and mixtures or alloys thereof.

13. A method according to claim 8, comprising the step of:
(a5) introducing a gas into the vacuum chamber to form a coating on the substrate which is a compound of the gas and the target.

14. A system for coating a substrate comprising:
a vacuum chamber for locating the substrate;
an anode and cathode assembly capable of generating a plasma within the vacuum chamber from a target to thereby deposit the plasma on the substrate to form a coating;
a power supply capable of applying bias to the substrate,
wherein in use, said power supply applies a variable bias to the substrate as said plasma is deposited thereon.

15. A system as claimed in claim 14 wherein said power supply alternates said variable bias between a high negative bias pulse and a low negative bias pulse.

16. A system as claimed in claim 15 wherein said high negative bias pulse is selected from the group of the ranges consisting of −1800 V to −4,500 V and −2000 V to −2500 V.

17. A system as claimed in claim 15 wherein said low negative bias pulse is selected from the group of the ranges consisting of −50 V to −500 V and −100 V to −200 V.

18. A system as claimed in claim 14, wherein said power supply supplies said variable bias at a frequency of up to 10 kHz or from the range of 1 kHz to 3 kHz.

19. A system as claimed in claim 15, wherein said power supply supplies the pulse of said high negative bias pulse and a low negative bias pulse for a duration from the group consisting of 1 μs to 50 μs, 1 μs to 25 μs and 5 μs to 10 μs.

20. A system as claimed in claim 14, wherein said target is a metal or graphite.

21. A system as claimed in claim 20, wherein when said target is metal, said metal is selected from the group consisting of titanium, chromium, aluminium, gallium and mixtures or alloys thereof.

22. A system as claimed in claim 14, wherein a gas is provided in said vacuum chamber to form a coating on the substrate which is a compound of the gas and the target.

23. An apparatus for coating a substrate comprising:
a vacuum chamber for locating the substrate;
an anode and cathode assembly capable of generating a plasma within the vacuum chamber from a target;
a power supply capable of applying bias to the substrate,
wherein in use, said power supply applies a variable bias to said substrate as said plasma is deposited on said substrate to form a coating thereon.

24. An apparatus as claimed in claim 23, wherein said variable bias alternates between a high negative bias pulse and a low negative bias pulse.

25. An apparatus as claimed in claim 24, wherein said high negative bias pulse is in the range selected from the group consisting of −1800 V to −4,500 V and −2000 V to −2500 V.

26. An apparatus as claimed in claim 24, wherein said low negative bias pulse is in the range selected from the group consisting of −50 V to −500 V and −100 V to −200 V.

27. Use of a variable bias voltage for reducing stress in a coating deposited using an arc deposition apparatus.

28. Use of a variable bias voltage alternating between a high negative bias pulse is selected from the group of the ranges consisting of −1800 V to −4,500 V and −2000 V to −2500 V and a low negative bias pulse is selected from the group of the ranges consisting of −50 V to −500 V and −100 V to −200 V for reducing stress in a coating deposited using an FCVA source.
